(19) United States
(12) Patent Application Publication
(10) Pub. No.: US 2025/0147440 A1
(43) Pub. Date: May 8, 2025

(54) PELLICLES AND MEMBRANES FOR USE IN A LITHOGRAPHIC APPARATUS

(71) Applicant: ASML NETHERLANDS B.V., Veldhoven (NL)

(72) Inventors: Zomer Silvester HOUWELING, Utrecht (NL); Roman PUSHKAREV, Eindhoven (NL); Robbert Wilhelmus Elisabeth VAN DE KRUIJS, Nieuwegein (NL); Marcel David ACKERMANN, Enschede (NL)

(73) Assignee: ASML NETHERLANDS B.V., Veldhoven (NL)

(21) Appl. No.: 18/835,714

(22) PCT Filed: Jan. 10, 2023
(86) PCT No.: PCT/EP2023/050495

§ 371 Date: Aug. 2, 2024

(30) Foreign Application Priority Data
Feb. 24, 2022 (EP) 22158569.8

(51) Int. Cl. G03F 7/00; G03F 1/64

(52) U.S. Cl. CPC G03F 7/70983; G03F 1/64

(57) ABSTRACT

Novel membranes for use in a lithographic apparatus are disclosed. A first membrane includes a core substrate and a metal silicate layer. The metal silicate layer is an outermost layer of the first membrane. A second membrane includes a core substrate and an yttrium silicate layer. The yttrium silicate layer may be an outermost layer of the membrane or, alternatively, the yttrium silicate layer may be disposed between the core substrate and a layer of yttrium or yttrium oxide. The first and second membranes may be provided within an EUV lithographic apparatus. For example, the membranes may form part of a pellicle. The pellicle may be suitable for use adjacent to a reticle within an EUV lithographic apparatus. The membranes may form part of a dynamic gas lock. The membranes may form part of a spectral filter.

### CROSS-REFERENCE TO RELATED APPLICATIONS

This application claims priority of EP Application Serial No. 22158569.8 which was filed on Feb. 24, 2022 and which is incorporated herein in its entirety by reference.

### FIELD

The present invention relates to pellicles for use in a lithographic apparatus and associated methods for forming such pellicles. The present invention also relates to a lithographic apparatus comprising a membrane disposed in a path of a radiation beam of the lithographic apparatus (used for forming an image on a substrate).

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g., a mask) onto a layer of radiation-sensitive material (resist) provided on a substrate.

The wavelength of radiation used by a lithographic apparatus to project a pattern onto a substrate determines the minimum size of features that can be formed on that substrate. A lithographic apparatus that uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A patterning device (e.g., a mask) that is used to impart a pattern to a radiation beam in a lithographic apparatus may form part of a mask assembly. A mask assembly may include a pellicle that protects the patterning device from particle contamination. The pellicle may be supported by a pellicle frame.

It may be desirable to provide an apparatus and/or method that obviates or mitigates one or more problems associated with the prior art.

### SUMMARY

According to a first aspect of the present disclosure there is provided a membrane for use in a lithographic apparatus, the membrane comprising: a core substrate; and a metal silicate layer, wherein the metal silicate layer is an outermost layer of the membrane.

The membrane may be provided within an EUV lithographic apparatus.

For example, the membrane may form part of a pellicle. The pellicle may be suitable for use adjacent to a reticle within an EUV lithographic apparatus. In use, such a (reflective) reticle is illuminated with EUV radiation, for example from an illumination system. It will be appreciated that the reticle is configured to impart the radiation beam received from the illumination system with a pattern in its cross-section to form a patterned radiation beam. A projection system collects the (reflected) patterned radiation beam and forms a (diffraction-limited) image of the reticle on a substrate (for example a resist coated silicon wafer). Any contamination on the reticle will, in general, alter the image formed on the substrate, leading to printing errors.

To avoid particle contamination of the reticles, it is known to use a thin membrane, known as a pellicle, to protect the reticle. The pellicle is disposed in front of the reticle and prevents particles from the landing on the reticle. The pellicle is disposed such that it is not sharply imaged by the projection system and therefore particles on the pellicle do not interfere with the imaging process. It is desirable for the pellicle to be sufficiently thick that it stops particles from impinging on the reticle that would cause unacceptable printing errors but as thin as possible to reduce the absorption of EUV radiation by the pellicle. It is known to provide an outer layer on a pellicle that has better stability within the environment of an EUV lithographic apparatus in order to protect other layers of the pellicle. Such an outer layer may be referred to as a capping layer.

Alternatively, the membrane may form part of a dynamic gas lock. Alternatively, the membrane may form part of a spectral filter.

Designing a membrane that is stable in the environment within the lithographic apparatus is challenging for several reasons. First, the environment within the lithographic apparatus is alternatingly reducing and oxidizing in the presence of EUV photons, a high temperature, free radicals, ions and electrons. Second, in order to minimize attenuation of the EUV radiation, it is desirable to provide a capping layer with a small thickness, say of the order of 5 nm. For many materials, such a layer thickness when provided in the environment of the EUV lithographic apparatus are subject to significant degradation. For example, in general, most nitrides tend to oxidize, most oxides tend to reduce, and most metals tend to de-wet when they are provided in a layer of such a small thickness. Furthermore, most materials tend to be subject to thermally induced outgassing and desorption phenomena.

The membrane according to the first aspect is particularly advantageous, as now discussed.

The metal silicate layer may be generally of the form of MeₓSi_{y}O_{z}, where Me is a metal. Advantageously, it has been found that a metal silicate layer is suitable for use as a protective layer for other parts of the pellicle. In particular, in conditions experienced in use within an EUV lithographic apparatus, such a metal silicate layer has been found to be stable, even for thicknesses of the order of 5 nm or less (such thicknesses advantageously reduce the absorption of EUV radiation by the pellicle to an acceptable level). In particular, it has been found that at elevated temperatures metal silicate layers on a membrane are not susceptible to oxidation, not susceptible to thermal de-wetting, not susceptible to etching in the presence of hydrogen radicals, hydrogen ions (with energies of the order of up to ˜ 50 eV) and hydrogen plasma with energies in the range 1-30 eV, even with thicknesses smaller than 5 nm.

In use, a pellicle will receive a significant heat load from the EUV radiation. It is known to provide a metal layer on a pellicle to act as an emissive layer so as to reduce an operating temperature of the pellicle. Typically, metals absorb EUV radiation well and have a relatively high extinction coefficient for EUV radiation (for example relative to a bulk of the pellicle which may be formed, for example, from silicon). Therefore, it is desirable to minimize the thickness of such an emissive layer, whilst still reducing the operating temperature of pellicle to an acceptable level. A desirable thickness of a metal emissive layer may be of the order of 5 nm. However, metal layers having such thicknesses are susceptible to thermal de-wetting and degrade unacceptably quickly within the environment of an EUV lithographic apparatus. It has previously been suggested to use a metal silicate layer (the metal being ruthenium, zirconium or hafnium) between a silicon substrate and a metal (emissive) layer as it has been found that such an intermediate metal silicate layer can prevent or reduce the de-wetting of the metal layer. In contrast to such an intermediate metal silicate layer, the membrane according to the first aspect is an outermost layer of the membrane and acts as a protective layer to other parts of the membrane.

The membrane may comprise two metal silicate layers. The two metal silicate layers may be disposed on opposite sides of the core substrate. Each metal silicate layer may be an outermost layer of the membrane.

The metal of at least one of the metal silicate layer(s) may be yttrium.

That is, the metal silicate layer(s) may comprise yttrium silicate (YₓSi_{y}O_{z}). For example, the metal silicate layer(s) may comprise yttrium orthosilicate (Y₂Si₁O₅) or the ceramic Y₂Si₂O₇.

The metal of at least one of the metal silicate layer(s) may be ruthenium.

At least one of the metal silicate layer(s) may be stable within the environment of an EUV lithographic apparatus.

It will be appreciated that a metal silicate layer being stable is intended to mean the metal silicate layer is not susceptible to oxidation, not susceptible to thermal de-wetting and not susceptible to plasma etching.

It will be appreciated that within the environment of an EUV lithographic apparatus the membrane may typically cycle through a range of temperatures of 20-600° C. Within the lithographic apparatus the hydrogen plasma may have energies in the range 1-30 eV. Typical hydrogen ion energies encountered within the lithographic apparatus may be, for example, ion energies of up to ˜ 50 eV (for example 1-30 e V).

A thickness of at least one of the metal silicate layer(s) may be less than or equal to 10 nm.

A thickness of at least one of the metal silicate layer(s) may be less than or equal to 5 nm.

In some embodiments, the thickness of the metal silicate layer(s) may be less than or equal to around 4.5 nm. In some embodiments, the thickness of the metal silicate layer(s) may be less than or equal to around 3.5 nm.

An EUV transmissivity of at least one of the metal silicate layer(s) may be 96% or more.

In some embodiments, an EUV transmissivity of at least one of the metal silicate layers is 97% or more. In some embodiments, an EUV transmissivity of at least one of the metal silicate layers is 98% or more. In some embodiments, an EUV transmissivity of at least one of the metal silicate layers is 99% or more.

According to a second aspect of the present disclosure there is provided a membrane for use in a lithographic apparatus, the membrane comprising an yttrium silicate layer.

In use, the membrane may be provided within an EUV lithographic apparatus. For example, the membrane may form part of a pellicle. Alternatively, the membrane may form part of a dynamic gas lock. Alternatively, the membrane may form part of a spectral filter. As explained above, designing a membrane that is stable in the environment within the lithographic apparatus is challenging for several reasons.

The membrane according to the second aspect is particularly advantageous, as now discussed.

The yttrium silicate layer may be generally of the form of YₓSi_{y}O_{z}. Advantageously, it has been found that an yttrium silicate layer is suitable for use as a protective layer for other parts of the pellicle. In particular, in conditions experienced in use within an EUV lithographic apparatus, such an yttrium silicate layer has been found to be stable, even for thicknesses of the order of 5 nm or less (such thicknesses advantageously reduce the absorption of EUV radiation by the pellicle to an acceptable level). In particular, it has been found that at elevated temperatures yttrium silicate layers on a membrane are particularly stable (for example, not susceptible to oxidation, not susceptible to thermal de-wetting, and not susceptible to plasma etching), even with thicknesses smaller than 5 nm.

The yttrium silicate layer may comprise yttrium orthosilicate (Y₂Si₁O₅) or the ceramic Y₂Si₂O₇.

The membrane may further comprise a core substrate.

The membrane may comprise two yttrium silicate layers. The two yttrium silicate layers may be disposed on opposite sides of the core substrate.

At least one of the yttrium silicate layer(s) may be an outermost layer of the membrane.

At least one of the yttrium silicate layer(s) may be disposed between the core substrate and a layer of yttrium or yttrium oxide.

A thickness of at least one of the yttrium silicate layer(s) may be less than or equal to 10 nm.

A thickness of at least one of the yttrium silicate layer(s) may be less than or equal to 5 nm.

In some embodiments, the thickness of the yttrium silicate layer(s) may be less than or equal to around 4.5 nm. In some embodiments, the thickness of the yttrium silicate layer(s) may be less than or equal to around 3.5 nm.

An EUV transmissivity of at least one of the yttrium silicate layer(s) may be 96% or more.

In some embodiments, an EUV transmissivity of at least one of the yttrium silicate layer(s) is 97% or more. In some embodiments, an EUV transmissivity of at least one of the yttrium silicate layer(s) is 98% or more. In some embodiments, an EUV transmissivity of at least one of the yttrium silicate layer(s) is 99% or more.

The core substrate of the membrane of either the first aspect or the second aspect of the present disclosure may comprise a silicon-based substrate.

The silicon based substrate may comprise silicon and/or silicon nitride (SiNₓ).

The core substrate of the membrane of either the first aspect or the second aspect of the present disclosure may comprise a metallic layer.

Such a metal layer can act as an emissivity layer, improving removal of the EUV heat load from the membrane.

The membrane of either the first aspect or the second aspect of the present disclosure may further comprise a seed layer disposed between the silicon-based substrate and the metallic layer.

According to a third aspect of the present disclosure there is provided a pellicle for use in a lithographic apparatus, the pellicle comprising the membrane of any preceding claim.

The pellicle may further comprise a border portion at a peripheral portion of the membrane.

The pellicle may further comprise a frame arranged to support the pellicle.

According to a fourth aspect of the present disclosure there is provided a patterning device and pellicle assembly comprising: a patterning device; and the pellicle of the third aspect of the present disclosure releasably engaged with said patterning device.

According to a fifth aspect of the present disclosure there is provided a lithographic apparatus operable to form an image of a patterning device on a substrate using a radiation beam, the lithographic apparatus comprising the patterning device and pellicle assembly of the fourth aspect of the present disclosure.

According to a sixth aspect of the present disclosure there is provided a lithographic apparatus operable to form an image of a patterning device on a substrate using a radiation beam, the lithographic apparatus comprising the membrane of the first or second aspects of the present disclosure disposed in a path of the radiation beam.

The membrane may form part of a dynamic gas lock.

The membrane may form part of a spectral filter.

The membrane may form part of a pellicle.

According to a seventh aspect of the present disclosure there is provided a method for forming a membrane according to the first or second aspect of the present disclosure, the method comprising: providing a silicon-based substrate; applying a metal or metal oxide layer on the silicon-based substrate to form an intermediate membrane; and annealing the intermediate membrane so form the metal silicate layer from the silicon-based substrate and the metal or metal oxide layer.

The silicon-based substrate may comprise an outer layer of a silicon oxide or a silicon oxynitride.

The silicon-based substrate may further comprise a silicon substrate. The silicon substrate may, for example, comprise a polycrystalline silicon substrate.

Annealing the intermediate membrane may comprise elevating a temperature of the intermediate membrane to at least 700° C. for an annealing time period.

In some embodiments, annealing the intermediate membrane may comprise elevating a temperature of the intermediate membrane to at least 800° C. for the time annealing period. In some embodiments, annealing the intermediate membrane may comprise elevating a temperature of the intermediate membrane to at least 900° C. for the time annealing period.

It will be appreciated that the annealing time period may be sufficiently long to form the metal silicate layer from the silicon-based substrate and the metal or metal oxide layer. Therefore, the annealing time period may be selected based on the materials (for example the metal used and the type of silicon-based substrate), the thickness of the metal or metal oxide layer and/or a desired target thickness of the metal silicate layer. For a metal silicate layer with a thickness of less than 10 nm (for example less than 5 nm) a relatively short annealing time may be sufficient.

The annealing time period may be sufficiently long to ensure that substantially all of the metal or metal oxide layer is converted into the metal silicate layer.

In some embodiments, the annealing time period may be longer than necessary, for example, to ensure that substantially all of the metal or metal oxide layer is converted into the metal silicate layer.

The annealing time period may be at least 1 hour.

In some embodiments, the annealing time period may be at least 2 hours.

Annealing the intermediate membrane may occur in the presence of nitrogen gas at a pressure of 1 bar.

In other embodiments, annealing of the intermediate membrane may occur in vacuum. In some other embodiments, annealing of the intermediate membrane may occur in-situ (for example in a lithographic apparatus). Such in-situ annealing may be achieved by exposure of the membrane to EUV radiation.

It will be appreciated that one or more aspects or features described above or referred to in the following description may be combined with one or more other aspects or features.

### BRIEF DESCRIPTION OF THE DRAWINGS

Embodiments of the invention will now be described, by way of example only, with reference to the accompanying schematic drawings, in which:

FIG. 1 is a schematic illustration of a lithographic system comprising a lithographic apparatus and a radiation source;

FIG. 2 is a schematic illustration of a first embodiment of a new membrane for use in a lithographic apparatus of the type shown in FIG. 1;

FIG. 3 is a schematic illustration of a second embodiment of a new membrane for use in a lithographic apparatus of the type shown in FIG. 1;

FIG. 4 is a schematic illustration of a third embodiment of a new membrane for use in a lithographic apparatus of the type shown in FIG. 1;

FIG. 5 is a schematic illustration of a fourth embodiment of a new membrane for use in a lithographic apparatus of the type shown in FIG. 1;

FIG. 6 is a schematic illustration of a method for forming a novel membrane of the type shown in FIGS. 2 to 5;

FIG. 7 shows an intermediate membrane formed by the first and second steps of the method shown in FIG. 6;

FIG. 8A depicts the output of the third step of the method shown in FIG. 6 for an embodiment of the method which results in a membrane of the type shown in FIG. 2; and

FIG. 8B depicts the output of the third step of the method shown in FIG. 6 for an embodiment of the method which results in a membrane of the type shown in FIG. 4.

### DETAILED DESCRIPTION

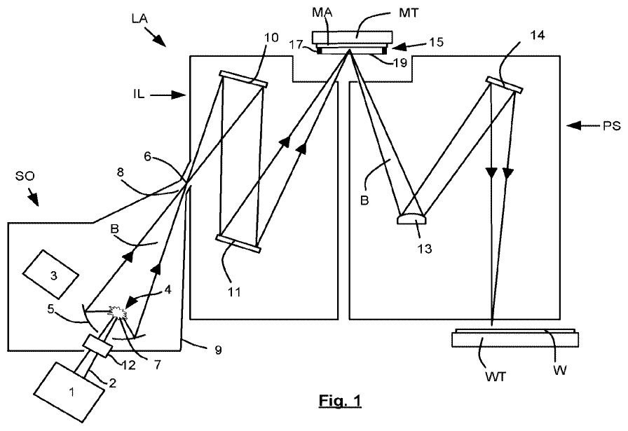

FIG. 1 shows a lithographic system. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a reticle assembly 15 including a patterning device MA (e.g., a reticle or mask), a projection system PS and a substrate table WT configured to support a substrate W. The illumination system IL is configured to condition the radiation beam B before it is incident upon the patterning device MA. The projection system is configured to project the radiation beam B (now patterned by the patterning device MA) onto the substrate W. The substrate W may include previously formed patterns. Where this is the case, the lithographic apparatus aligns the patterned radiation beam B with a pattern previously formed on the substrate W.

The radiation source SO; the illumination system IL; the region adjacent the support structure MT and the patterning device MA; and the projection system PS may all be constructed and arranged such that they can be isolated from the external environment. A gas at a pressure below atmospheric pressure (e.g., hydrogen) may be provided in the radiation source SO. A vacuum may be provided in the illumination system IL; the region adjacent the support structure MT and the patterning device MA; and/or the projection system PS. A small amount of gas (e.g., hydrogen) at a pressure well below atmospheric pressure may be provided in the illumination system IL; the region adjacent the support structure MT and the patterning device MA; and/or the projection system PS.

The radiation source SO shown in FIG. 1 is of a type that may be referred to as a laser produced plasma (LPP) source. A laser 1, which may for example be a CO2 laser, is arranged to deposit energy via a laser beam 2 into a fuel, such as tin (Sn) that is provided from a fuel emitter 3. Although tin is referred to in the following description, any suitable fuel may be used. The fuel may for example be in liquid form, and may for example be a metal or alloy. The fuel emitter 3 may comprise a nozzle configured to direct tin, e.g., in the form of droplets, along a trajectory towards a plasma formation region 4. The laser beam 2 is incident upon the tin at the plasma formation region 4. The deposition of laser energy into the tin creates a plasma 7 at the plasma formation region 4. Radiation, including EUV radiation, is emitted from the plasma 7 during de-excitation and recombination of ions of the plasma.

The EUV radiation is collected and focused by a near normal incidence radiation collector 5 (sometimes referred to more generally as a normal incidence radiation collector). The collector 5 may have a multilayer structure that is arranged to reflect EUV radiation (e.g., EUV radiation having a desired wavelength such as 13.5 nm). The collector 5 may have an elliptical configuration, having two ellipse focal points. A first focal point may be at the plasma formation region 4, and a second focal point may be at an intermediate focus 6, as discussed below.

In other embodiments of a laser produced plasma (LPP) source the collector 5 may be a so-called grazing incidence collector that is configured to receive EUV radiation at grazing incidence angles and focus the EUV radiation at an intermediate focus. A grazing incidence collector may, for example, be a nested collector, comprising a plurality of grazing incidence reflectors. The grazing incidence reflectors may be disposed axially symmetrically around an optical axis.

The radiation source SO may include one or more contamination traps (not shown). For example, a contamination trap may be located between the plasma formation region 4 and the radiation collector 5. The contamination trap may for example be a rotating foil trap, or may be any other suitable form of contamination trap.

The laser 1 may be separated from the radiation source SO. Where this is the case, the laser beam 2 may be passed from the laser 1 to the radiation source SO with the aid of a beam delivery system (not shown) comprising, for example, suitable directing mirrors and/or a beam expander, and/or other optics. The laser 1 and the radiation source SO may together be considered to be a radiation system.

Radiation that is reflected by the collector 5 forms a radiation beam B. The radiation beam B is focused at point 6 to form an image of the plasma formation region 4, which acts as a virtual radiation source for the illumination system IL. The point 6 at which the radiation beam B is focused may be referred to as the intermediate focus. The radiation source SO is arranged such that the intermediate focus 6 is located at or near to an opening 8 in an enclosing structure 9 of the radiation source SO.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the reticle assembly 15 held by the support structure MT. The reticle assembly 15 includes a patterning device MA and a pellicle 19. The pellicle is mounted to the patterning device MA via a pellicle frame 17. The reticle assembly 15 may be referred to as a reticle and pellicle assembly 15. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 that are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system PS may include any number of mirrors (e.g., six mirrors).

The lithographic apparatus may, for example, be used in a scan mode, wherein the support structure (e.g., mask table) MT and the substrate table WT are scanned synchronously while a pattern imparted to the radiation beam is projected onto a substrate W (i.e., a dynamic exposure). The velocity and direction of the substrate table WT relative to the support structure (e.g., mask table) MT may be determined by the demagnification and image reversal characteristics of the projection system PS. The patterned radiation beam that is incident upon the substrate W may comprise a band of radiation. The band of radiation may be referred to as an exposure slit. During a scanning exposure, the movement of the substrate table WT and the support structure MT may be such that the exposure slit travels over an exposure field of the substrate W.

The radiation source SO and/or the lithographic apparatus that is shown in FIG. 1 may include components that are not illustrated. For example, a spectral filter may be provided in the radiation source SO. The spectral filter may be substantially transmissive for EUV radiation but substantially blocking for other wavelengths of radiation such as infrared radiation.

In other embodiments of a lithographic system the radiation source SO may take other forms. For example, in alternative embodiments the radiation source SO may comprise one or more free electron lasers. The one or more free electron lasers may be configured to emit EUV radiation that may be provided to one or more lithographic apparatus.

As was described briefly above, the reticle assembly 15 includes a pellicle 19 that is provided adjacent to the patterning device MA. The pellicle 19 is provided in the path of the radiation beam B such that radiation beam B passes through the pellicle 19 both as it approaches the patterning device MA from the illumination system IL and as it is reflected by the patterning device MA towards the projection system PS. The pellicle 19 comprises a thin film or membrane that is substantially transparent to EUV radiation (although it will absorb a small amount of EUV radiation). By EUV transparent pellicle or a film substantially transparent for EUV radiation herein is meant that the pellicle 19 is transmissive for at least 65% of the EUV radiation, preferably at least 80% and more preferably at least 90% of the EUV radiation. The pellicle 19 acts to protect the patterning device MA from particle contamination.

Whilst efforts may be made to maintain a clean environment inside the lithographic apparatus LA, particles may still be present inside the lithographic apparatus LA. In the absence of a pellicle 19, particles may be deposited onto the patterning device MA. Particles on the patterning device MA may disadvantageously affect the pattern that is imparted to the radiation beam B and therefore the pattern that is transferred to the substrate W. The pellicle 19 advantageously provides a barrier between the patterning device MA and the environment in the lithographic apparatus LA in order to prevent particles from being deposited on the patterning device MA.

The pellicle 19 is positioned at a distance from the patterning device MA that is sufficient that any particles that are incident upon the surface of the pellicle 19 are not in a field plane of the lithographic apparatus LA. This separation between the pellicle 19 and the patterning device MA acts to reduce the extent to which any particles on the surface of the pellicle 19 impart a pattern to the radiation beam B that is imaged onto the substrate W. It will be appreciated that where a particle is present in the beam of radiation B, but at a position that is not in a field plane of the beam of radiation B (for example not at the surface of the patterning device MA), then any image of the particle will not be in focus at the surface of the substrate W. In the absence of other considerations it may be desirable to position the pellicle 19 a considerable distance away from the patterning device MA. However, in practice the space which is available in the lithographic apparatus LA to accommodate the pellicle is limited due to the presence of other components. In some embodiments, the separation between the pellicle 19 and the patterning device MA may, for example, be approximately between 1 mm and 10 mm, for example between 1 mm and 5 mm, for example between 2 mm and 2.5 mm.

The pellicle may comprise a border portion and a membrane. The border portion of the pellicle may be hollow and generally rectangular and the membrane may be bounded by the border portion. As known in the art, one type of pellicle may be formed by deposition of one or more thin layers of material on a generally rectangular silicon substrate. The silicon substrate supports the one or more thin layers during this stage of the construction of the pellicle. Once a desired or target thickness and composition of layers has been applied, a central portion of the silicon substrate is removed by etching (this may be referred to as back etching). A peripheral portion of the rectangular silicon substrate is not etched (or alternatively is etched to a lesser extent than the central portion). This peripheral portion forms the border portion of the final pellicle while the one or more thin layers form the membrane of the pellicle (which is bordered by the border portion). The border portion of the pellicle may be formed from silicon.

A pellicle (for example comprising a membrane and a border) may require some support from a more rigid pellicle frame. The pellicle frame may provide two functions. First, the pellicle frame may support the pellicle and may also tension the pellicle membrane. Second, the pellicle frame may facilitate connection of the pellicle to a patterning device (reticle). It one known arrangement, the pellicle frame may comprise a main, generally rectangular body portion which is glued to the border portion of the pellicle and titanium attachment mechanisms that are glued to the side of this main body. Intermediate fixing members (known as studs) are affixed to the patterning device (reticle). The intermediate fixing members (studs) on the patterning device (reticle) may engage (for example releasably engage) with the attachment members of the pellicle frame.

Ideally the EUV transmissivity of the pellicle 19 is as high as possible. However, in practice, some portion of the EUV radiation beam B is absorbed by the pellicle 19. Since the pellicle 19 is disposed in the direct path of the EUV radiation beam B and the power of the radiation beam B is significant, in use, the pellicle 19 absorbs a significant amount of power. Furthermore, as stated above the region adjacent or in the vicinity of the reticle assembly 15 (which includes the pellicle 19) may be under vacuum conditions or may be provided with a gas (e.g., hydrogen) at a pressure well below atmospheric pressure, which limits the removal of the EUV heat load via conduction and convection. The high heat load received by the pellicle 19 in combination with this low operational ambient gas pressure can therefore result in significantly elevated temperatures for the membrane of the pellicle 19. In the conditions within the lithographic apparatus LA, the pellicle 19 may degrade over time. The low pressure hydrogen gas provided within the lithographic apparatus LA forms a hydrogen plasma in the presence of the EUV radiation (during exposure). It has been found that hydrogen ions and hydrogen free radicals from the hydrogen plasma can chemically affect (for example reduce or etch) pellicles 19, limiting the potential lifetime of the pellicles. The environment within the lithographic apparatus LA is alternatingly reducing and oxidizing in the presence of EUV radiation beam B, free radicals, ions and electrons. Furthermore, the relevant degradation processes often proceed more rapidly at elevated temperatures.

The relevant degradation processes often also occur at the exterior surface of the membrane of the pellicle 19. Therefore one way to raise the pellicle lifetime is to apply a layer to the external surfaces of a pellicle that has a better stability within the environment of an EUV lithographic apparatus (for example, a layer that has increased resistance to plasma etching). Such an outer layer may be referred to as a capping layer. As stated above, in order to avoid high temperatures of the membrane the EUV transmission of the pellicle 19 should be as high as possible (whilst still functioning to block particles from impinging on the patterning device). The choice of the material for the capping layer should be based on the compromise between performance properties (EUV transmission) and protective properties (protection of the layer itself and all the underlying layers).

Some embodiments of the present disclosure relate to a new type of membrane (which may form part of the pellicle 19) and methods of forming such a membrane.

FIG. 2 is a schematic illustration of a first embodiment of a new membrane 100 for use in a lithographic apparatus LA (for example as the membrane of the pellicle 19). The membrane comprises: a core substrate 102; and a metal silicate layer 104. The metal silicate layer 104 is an outermost layer of the membrane 100. The metal silicate layer 104 may be considered to be a capping layer.

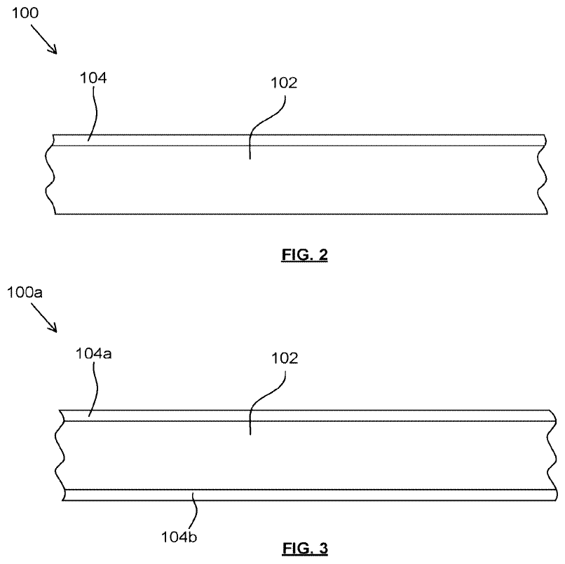

FIG. 3 is a schematic illustration of a second embodiment of a new membrane 100a for use in a lithographic apparatus LA (for example as the membrane of the pellicle 19). The membrane 100a comprises: a core substrate 102; and two metal silicate layers 104a, 104b. The two metal silicate layers 104a, 104b are disposed on opposite sides of the core substrate 102. Each metal silicate layer 104a, 104b is an outermost layer of the membrane 100a. The metal silicate layers 104a, 104b may be considered to be capping layers.

The membrane 100, 100a may form part of a pellicle 19 of the type shown in FIG. 1 and described above. As explained above, it is desirable for the pellicle 19 to be sufficiently thick that it stops particles from impinging on the reticle MA that would cause unacceptable printing errors but as thin as possible to reduce the absorption of EUV radiation by the pellicle 19.

Alternatively, the membrane 100, 100a may form part of a dynamic gas lock. Alternatively, the membrane 100, 100a may form part of a spectral filter.

Designing a membrane that is stable in the environment within the lithographic apparatus LA is challenging for several reasons. First, the environment within the lithographic apparatus LA is alternatingly reducing and oxidizing in the presence of EUV photons, a high temperature, free radicals, ions and electrons. Second, in order to minimize attenuation of the EUV radiation beam B, it is desirable to provide a capping layer with a small thickness, say of the order of 5 nm or smaller. For many materials, such a layer thickness would be subject to significant degradation when provided in the environment of the EUV lithographic apparatus LA. For example, in general, most nitrides tend to oxidize, most oxides tend to reduce, and most metals tend to de-wet when they are provided in a layer of such a small thickness. Furthermore, most materials tend to be subject to thermally induced outgassing and desorption phenomena.

The membranes 100, 100a shown schematically in FIGS. 2 and 3 are particularly advantageous, as now discussed.

The metal silicate layer(s) 104, 104a, 104b may be generally of the form of MeₓSi_{y}O_{z}, where Me is a metal. Advantageously, it has been found that a metal silicate layer is suitable for use as a protective layer for other parts of the pellicle 19. In particular, in conditions experienced in use within an EUV lithographic apparatus LA, such a metal silicate layer 104, 104a, 104b has been found to be stable, even for thicknesses of the order of 5 nm or less (such thicknesses advantageously reduce the absorption of EUV radiation by a pellicle 19 to an acceptable level). In particular, it has been found that at elevated temperatures metal silicate layer(s) 104, 104a, 104b on a membrane 100, 100a are not susceptible to oxidation, not susceptible to thermal de-wetting, not susceptible to etching in the presence of hydrogen radicals, hydrogen ions (with energies of the order of up to ˜ 50 eV) and hydrogen plasma with energies in the range 1-30 eV, even with thicknesses smaller than 5 nm.

In use, a pellicle 19 will receive a significant heat load from the EUV radiation. It is known to provide a metal layer on a pellicle 19 to act as an emissive layer so as to reduce an operating temperature of the pellicle 19. Typically, metals absorb EUV radiation well and have a relatively high extinction coefficient for EUV radiation (for example relative to a bulk of the pellicle 19 which may be formed, for example, from silicon). Therefore, it is desirable to minimize the thickness of such an emissive layer, whilst still reducing the operating temperature of pellicle 19 to an acceptable level. A desirable thickness of a metal emissive layer may be of the order of 5 nm. However, metal layers having such thicknesses are susceptible to thermal de-wetting and degrade unacceptably quickly within the environment of an EUV lithographic apparatus LA. It has previously been suggested to use a metal silicate layer between a silicon substrate and a metal (emissive) layer as it has been found that such an intermediate metal silicate layer can prevent or reduce the de-wetting of the metal layer. In contrast to such an intermediate metal silicate layer, the or each metal silicate layer 104, 104a, 104b of the membranes 100, 100a shown in FIGS. 2 and 3 is an outermost layer of the membrane 100, 100a and acts as a protective layer to other parts of the membrane 100, 100a.

In one embodiment that is known to perform well the metal of the metal silicate layer(s) 104, 104a, 104b is yttrium. That is, the metal silicate layer(s) 104, 104a, 104b may comprise yttrium silicate (YₓSi_{y}O_{z}). For example, the metal silicate layer(s) 104, 104a, 104b may comprise yttrium orthosilicate (Y₂Si₁O₅) or the ceramic Y₂Si₂O₇.

In another embodiment, the metal of the metal silicate layer(s) 104, 104a, 104b is ruthenium. That is, the metal silicate layer(s) 104, 104a, 104b may comprise ruthenium silicate (RuxSiyOz).

It is expected that there may be other metal silicates that may be stable within the environment of an EUV lithographic apparatus LA. Therefore, in other embodiments, the metal of the metal silicate layer(s) 104, 104a, 104b may be any metal whose metal silicate is stable within the environment of an EUV lithographic apparatus LA. It will be appreciated that a metal silicate layer being stable is intended to mean the metal silicate layer is not susceptible to oxidation, not susceptible to thermal de-wetting and not susceptible to plasma etching. It will be further appreciated that within the environment of an EUV lithographic apparatus LA the membrane 100, 100a may typically cycle through a range of temperatures of around 20-600° C. Within the lithographic apparatus LA the hydrogen plasma may have energies in the range 1-30 eV. Typical hydrogen ion energies encountered within the lithographic apparatus LA may be, for example, ion energies of up to ˜ 50 eV (for example 1-30 eV).

In some embodiments, a thickness of the or each metal silicate layer 104, 104a, 104b is less than or equal to 10 nm. In some embodiments, a thickness of the or each metal silicate layer 104, 104a, 104b is less than or equal to 5 nm. In some embodiments, the thickness of the metal silicate layer(s) 104, 104a, 104b may be less than or equal to around 4.5 nm. In some embodiments, the thickness of the metal silicate layer(s) 104, 104a, 104b may be less than or equal to around 3.5 nm.

In some embodiments, an EUV transmissivity of the or each metal silicate layer 104, 104a, 104b is 96% or more. In some embodiments, an EUV transmissivity of the or each metal silicate layer 104, 104a, 104b is 97% or more. In some embodiments, an EUV transmissivity of the or each metal silicate layer 104, 104a, 104b is 98% or more. In some embodiments, an EUV transmissivity of the or each metal silicate layer 104, 104a, 104b is 99% or more.

FIG. 4 is a schematic illustration of a third embodiment of a new membrane 200 for use in a lithographic apparatus LA (for example as the membrane of the pellicle 19). The membrane comprises: a core substrate 202; an yttrium silicate layer 204; and an outer layer 206. The yttrium silicate layer 204 is disposed between the core substrate 202 and the outer layer 206 of the membrane 200. The outer layer 206 may comprise yttrium or yttrium oxide.

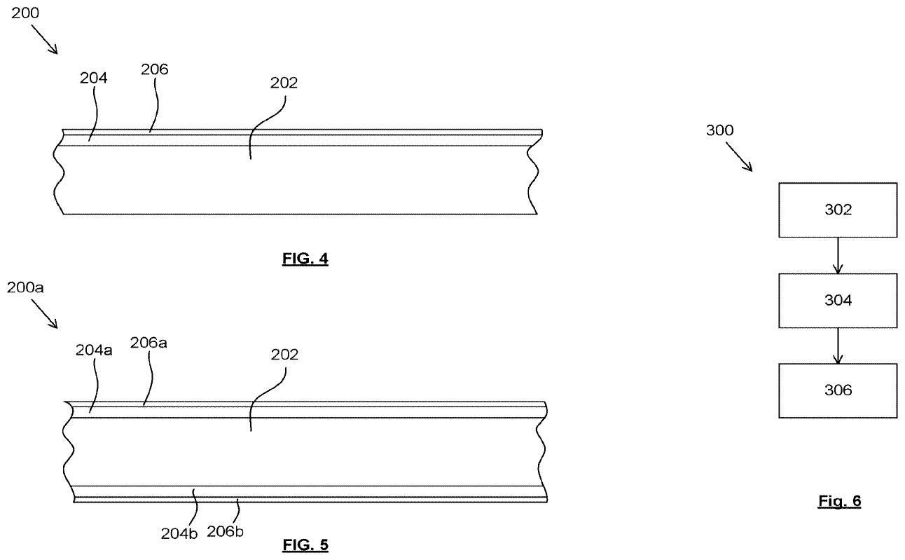

FIG. 5 is a schematic illustration of a fourth embodiment of a new membrane 200a for use in a lithographic apparatus LA (for example as the membrane of the pellicle 19). The membrane 200a comprises: a core substrate 202; two yttrium silicate layers 204a, 204b; and two outer layers 206a, 206b. The two yttrium silicate layers 204a, 204b are disposed on opposite sides of the core substrate 102. Each yttrium silicate layer 204a, 204b is disposed between the core substrate 202 and one of the outer layers 206a, 206b of the membrane 200a. The outer layers 206a, 206b may comprise yttrium or yttrium oxide.

The membranes 200, 200a may form part of a pellicle 19 of the type shown in FIG. 1 and described above. As explained above, it is desirable for the pellicle 19 to be sufficiently thick that it stops particles from impinging on the reticle MA that would cause unacceptable printing errors but as thin as possible to reduce the absorption of EUV radiation by the pellicle 19. Alternatively, the membranes 200, 200a may form part of a dynamic gas lock. Alternatively, the membrane 200, 200a may form part of a spectral filter.

As previously discussed, designing a membrane that is stable in the environment within the lithographic apparatus LA is challenging for several reasons. The membranes 200, 200a shown schematically in FIGS. 4 and 5 are particularly advantageous, as now discussed.

The yttrium silicate layer(s) 204, 204a, 204b may be generally of the form of YₓSi_{y}O_{z}. Advantageously, it has been found that an yttrium silicate layer is suitable for use as a protective layer for other parts of the pellicle 19. In particular, in conditions experienced in use within an EUV lithographic apparatus LA, such an yttrium silicate layer 204, 204a, 204b has been found to be stable, even for thicknesses of the order of 5 nm or less (such thicknesses advantageously reduce the absorption of EUV radiation by a pellicle 19 to an acceptable level). In particular, it has been found that at elevated temperatures yttrium silicate layer(s) 204, 204a, 204b on a membrane 200, 200a are not susceptible to oxidation, not susceptible to thermal de-wetting, not susceptible to etching in the presence of hydrogen radicals, hydrogen ions (with energies of the order of up to ˜50 eV) and hydrogen plasma with energies in the range 1-30 eV, even with thicknesses smaller than 5 nm.

In some embodiments, a thickness of the or each yttrium silicate layer 204, 204a, 204b is less than or equal to 10 nm. In some embodiments, a thickness of the or each yttrium silicate layer 204, 204a, 204b is less than or equal to 5 nm. In some embodiments, the thickness of the yttrium silicate layer(s) 204, 204a, 204b may be less than or equal to around 4.5 nm. In some embodiments, the thickness of the yttrium silicate layer(s) 204, 204a, 204b may be less than or equal to around 3.5 nm.

In some embodiments, an EUV transmissivity of the or each yttrium silicate layer 204, 204a, 204b is 96% or more. In some embodiments, an EUV transmissivity of the or each yttrium silicate layer 204, 204a, 204b is 97% or more. In some embodiments, an EUV transmissivity of the or each yttrium silicate layer 204, 204a, 204b is 98% or more. In some embodiments, an EUV transmissivity of the or each yttrium silicate layer 204, 204a, 204b is 99% or more.

The core substrate 102, 202 of the membranes 100, 100a, 200, 200a may comprise a silicon-based substrate. The silicon based substrate may, for example, comprise silicon and/or silicon nitride (SiNₓ).

In some embodiments, the core substrate 102, 202 of the membrane 100, 100a, 200, 200a may comprise a metallic layer. Such a metal layer can act as an emissivity layer, improving removal of the EUV heat load from the membrane 100, 100a, 200, 200a.

The membrane 100, 100a, 200, 200a may further comprise a seed layer disposed between the silicon-based substrate and the metallic layer of the core substrate 102, 202.

A pellicle 19 of the type shown in FIG. 1 and described above may comprise a novel membrane 100, 100a, 200, 200a of the type shown above. Such a pellicle 19 may further comprise a border portion at a peripheral portion of the membrane 100, 100a, 200, 200a. Additionally or alternatively, such a pellicle 19 may further comprise a frame arranged to support the pellicle 19, as is known in the art.

A pellicle 19 comprising a novel membrane 100, 100a, 200, 200a of the type shown above may form part of a patterning device and pellicle assembly 15 also comprising a patterning device MA, the pellicle 19 being releasably engaged with said patterning device MA.

FIG. 6 is a schematic illustration of a method 300 for forming a novel membrane 100, 100a, 200, 200a.

First, the method 300 comprises a step 302 of providing a silicon-based substrate. The silicon-based substrate may comprise an outer layer of a silicon oxide or a silicon oxynitride. The silicon-based substrate may further comprise a silicon substrate. The silicon substrate may, for example, comprise a polycrystalline silicon substrate.

Next, the method 300 comprises a step 304 of applying a metal or metal oxide layer (MeOₓ) on the silicon-based substrate to form an intermediate membrane. The thickness of the metal or metal oxide layer applied in step 304 may be less than 5 nm. For example, the thickness of the metal or metal oxide layer applied in step 304 may be less than 4 nm. For example, the thickness of the metal or metal oxide layer applied in step 304 may be less than 3 nm. For example, the thickness of the metal or metal oxide layer applied in step 304 may be less than 2 nm. For example, the thickness of the metal or metal oxide layer applied in step 304 may be less than 1 nm. For example, the thickness of the metal or metal oxide layer applied in step 304 may be less than 0.5 nm. The silicon-based substrate may comprise a barrier layer (such as SiO₂) which may have substantially the same thickness as the thickness of the metal or metal oxide layer applied in step 304.

Finally, the method 300 comprises a step 306 of annealing the intermediate membrane to form the metal silicate layer from the silicon-based substrate and the metal or metal oxide layer. As a result of this annealing of the intermediate membrane the metal or metal oxide layer may react partially or fully with the silicon-based substrate so as to form the metal silicate layer.

The annealing of the intermediate membrane may comprise elevating a temperature of the intermediate membrane to at least 700° C. for an annealing time period. In some embodiments, annealing the intermediate membrane may comprise elevating a temperature of the intermediate membrane to at least 800° C. for the time annealing period. In some embodiments, annealing the intermediate membrane may comprise elevating a temperature of the intermediate membrane to at least 900° C. for the time annealing period.

It will be appreciated that the annealing time period may be sufficiently long to form the metal silicate layer from the silicon-based substrate and the metal or metal oxide layer. Therefore, the annealing time period may be selected based on the materials (for example the metal used and the type of silicon-based substrate), the thickness of the metal or metal oxide layer and/or a desired target thickness of the metal silicate layer. For a metal silicate layer with a thickness of less than 10 nm (for example less than 5 nm) a relatively short annealing time may be sufficient. In some embodiments, the annealing time period is sufficiently long to ensure that substantially all of the metal or metal oxide layer is converted into the metal silicate layer. In some embodiments, the annealing time period may be longer than necessary, for example, to ensure that substantially all of the metal or metal oxide layer is converted into the metal silicate layer. For example, in some embodiments, the annealing time period may be at least 1 hour. In some embodiments, the annealing time period may be at least 2 hours.

Annealing the intermediate membrane may occur in the presence of nitrogen gas at a pressure of 1 bar. In other embodiments, annealing of the intermediate membrane may occur in vacuum. In some other embodiments, annealing of the intermediate membrane may occur in-situ (for example in a lithographic apparatus LA). Such in-situ annealing may be achieved by exposure of the membrane to EUV radiation with the lithographic apparatus LA.

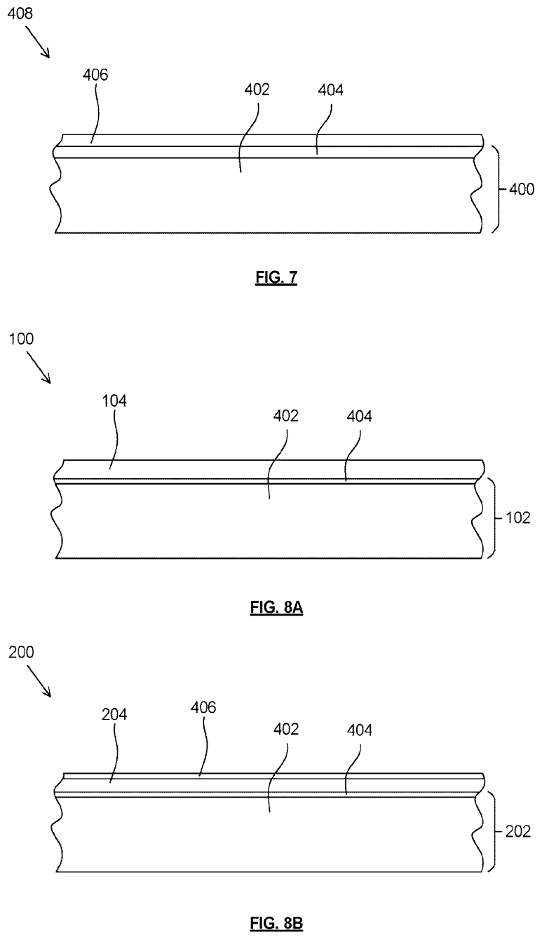

The first and second steps 302, 304 of the method shown in FIG. 6 are represented schematically in FIG. 7. In particular, a silicon-based substrate 400 is provided. In this example, the silicon-based substrate 400 comprises a silicon substrate 402 and an outer layer 404 of a silicon oxide or a silicon oxynitride. In step 304, a metal or metal oxide layer 406 is applied on the silicon-based substrate 400, in particular on the layer 404 of a silicon oxide or a silicon oxynitride, to form an intermediate membrane 408.

The output of the third step 306 of the method shown in FIG. 6 is represented schematically in FIGS. 8A and 8B. FIG. 8A depicts an embodiment of the method which results in a membrane 100 of the type shown in FIG. 2. FIG. 8B depicts an embodiment of the method which results in a membrane 200 of the type shown in FIG. 4.

As shown in FIG. 8A, the intermediate membrane 408 has been annealed so as to form a metal silicate layer 104 from the silicon-based substrate 400 and the metal or metal oxide layer 406. In particular, the layer 404 of a silicon oxide or a silicon oxynitride and the metal or metal oxide layer 406 have been combined by the annealing process so as to form the metal silicate layer 104. After the annealing process, the layer 404 of a silicon oxide or a silicon oxynitride may be partially (as shown in FIG. 8A) or completely depleted. In this embodiment, after the annealing process, the metal oxide layer 406 is completely depleted such that the metal silicate layer 104 is an outermost layer of the resultant membrane 100.

As shown in FIG. 8B, the intermediate membrane 408 has been annealed so as to form a metal silicate layer 204 from the silicon-based substrate 400 and the metal or metal oxide layer 406. In particular, the layer 404 of a silicon oxide or a silicon oxynitride and the metal or metal oxide layer 406 have been combined by the annealing process so as to form the metal silicate layer 204. After the annealing process, the layer 404 of a silicon oxide or a silicon oxynitride may be partially (as shown in FIG. 8B) or completely depleted. In this embodiment, after the annealing process, the metal oxide layer 406 is partially depleted such that the metal silicate layer 104 is disposed between the core substrate 202 and the metal oxide layer 406 of the resultant membrane 200.

The method 300 shown in FIG. 6, and described above with reference to FIGS. 7 to 8B, was used to form membranes 100, 100a, 200, 200a of the types shown in FIGS. 2 to 5. First a SiNₓ-coated silicon wafer was provided (see step 302). Next, using physical vapour-deposition (PVD) various thicknesses of metal oxides were deposited on the SiNₓ-coated silicon wafer (see step 304). In particular, yttrium oxide (Y₂O₃), aluminium oxide (Al₂O₃), zirconium oxide (ZrO₂) and hafnium oxide (HfO₂) were all deposited via PVD. Subsequently, these deposited metal oxides were exposed to the following conditions (see step 306): thermal annealing at 900° C. in the presence of nitrogen gas at a pressure of 1 bar for 2 hours. This thermal annealing was performed in a tube oven at a pressure of 1 bar with a purging an nitrogen gas flow provided from one end of the tube oven while the other end of the tube oven was open to ambient conditions.

As a combined result of the deposition of the materials onto a silicon containing under layer (SiNₓ) with a subsequent thermal anneal treatment, the metal oxide films formed a metal silicate layer. This has been confirmed using x-ray photoelectron spectroscopy (XPS) when the thickness of the metal oxide was of the order of 5 nm or less.

After formation of an yttrium silicate layer, the resultant membrane 100, 100a, 200, 200a was subject to the following conditions: (i) exposure to thermal hydrogen radicals with a flux of 10²¹/cm² at a temperature of 700° C.; (ii) exposure to 50 eV hydrogen ions with a flux of 10¹⁹/cm² at a temperature of 650° C.; or (iii) exposure to ˜8 eV hydrogen plasma with an ion flux of 10¹⁹/cm² at a temperature of 550° C. It was found that the yttrium silicate was stable under these conditions (for example based on XPS analysis). Furthermore, it was found that the hydrogen plasma etching rate of the underlying SiNₓ substrate was reduced from 0.15 nm/min to 0.0 nm/min.

The EUV absorption (extinction) coefficient of Y₂Si₁O₅ is 0.0114 nm⁻¹. Therefore, the material has an EUV transmission of 90% at a thickness of about 9 nm. If the material at this thickness meets pellicle specifications then it may serve as pellicle core material.

However, in some embodiments, the yttrium silicate is provided as a capping layer, in which case less material is required. A capping layer of Y₂Si₁O₅ having a thickness of 2.5 nm applied as protective layer on each side of a pellicle core has an EUV transmission of 94.5%. Thus when applied on a pellicle core of 95.3% this results in a total EUV transmission of 90%.

As an alternative to the method 300 shown in FIG. 6, in some embodiments a metal silicate layer (for example an yttrium silicate layer) may be directly deposited onto a base substrate 102, 202. For example, this may be achieved using physical vapour-deposition (PVD). For such embodiments, the base substrate 102, 202 may be a silicon substrate and this process allows for enhanced control over the thickness of the metal silicate layer.

References to a mask or reticle in this document may be interpreted as references to a patterning device (a mask or reticle is an example of a patterning device) and the terms may be used interchangeably. In particular, the term mask assembly is synonymous with reticle assembly and patterning device assembly.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

The term “EUV radiation” may be considered to encompass electromagnetic radiation having a wavelength within the range of 4-20 nm, for example within the range of 13-14 nm. EUV radiation may have a wavelength of less than 10 nm, for example within the range of 4-10 nm such as 6.7 nm or 6.8 nm.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A membrane for use in a lithographic apparatus, the membrane comprising:
a core substrate; and
a metal silicate layer,
wherein the metal silicate layer is an outermost layer of the membrane.

2. The membrane of claim 1, wherein the membrane comprises two metal silicate layers, the two metal silicate layers being disposed on opposite sides of the core substrate, and each metal silicate layer being an outermost layer of the membrane.

3. The membrane of claim 1, wherein the metal of the metal silicate layer is yttrium.

4. The membrane of claim 1, wherein the metal of the metal silicate layer is ruthenium.

5. (canceled)

6. The membrane of claim 1, wherein a thickness of the metal silicate layer is less than or equal to 10 nm.

7. (canceled)

8. The membrane of claim 1, wherein an EUV transmissivity of the metal silicate layer is 96% or more.

9. A membrane for use in a lithographic apparatus, the membrane comprising an yttrium silicate layer.

10. The membrane of claim 9, further comprising a core substrate.

11. The membrane of claim 10, wherein the membrane comprises two yttrium silicate layers, the two yttrium silicate layers being disposed on opposite sides of the core substrate.

12. The membrane of claim 9, wherein the yttrium silicate layer is an outermost layer of the membrane.

13. The membrane of claim 9, wherein the yttrium silicate layer is disposed between a core substrate and a layer of yttrium or yttrium oxide.

14. The membrane of claim 9, wherein a thickness of the yttrium silicate layer is less than or equal to 10 nm.

15. (canceled)

16. The membrane of claim 9, wherein an EUV transmissivity of the yttrium silicate layer is 96% or more.

17. (canceled)

18. The membrane of claim 1, wherein the core substrate of the membrane comprises a silicon-based substrate and/or a metallic layer.

19. (canceled)

20. A pellicle for use in a lithographic apparatus, the pellicle comprising the membrane of claim 1 and a border portion at a peripheral portion of the membrane.

21.-22. (canceled)

23. A patterning device and pellicle assembly comprising:
a patterning device; and
the pellicle of claim 20 engaged with the said patterning device.

24. (canceled)

25. A lithographic apparatus operable to form an image of a patterning device on a substrate using a radiation beam, the lithographic apparatus comprising the membrane of claim 1 disposed in a path of the radiation beam.

26. The lithographic apparatus of claim 25, wherein the membrane forms part of a dynamic gas lock, part of a spectral filter or part of a pellicle.

27.-28. (canceled)

29. A method for forming a membrane according to claim 1, the method comprising:
applying a metal or metal oxide layer on a silicon-based substrate to form an intermediate membrane; and
annealing the intermediate membrane so as to form the metal silicate layer from the silicon-based substrate and the metal or metal oxide layer.

30. The method of claim 29, wherein the silicon-based substrate comprises an outer layer of a silicon oxide or a silicon oxynitride.

31.-34. (canceled)
